(19) United States
(12) Patent Application Publication
(10) Pub. No.: US 2014/0308439 A1
(43) Pub. Date: Oct. 16, 2014

(54) METHOD OF PROTECTING PATIERNED MAGNETIC MATERIALS OF A STACK

(71) Applicant: SEAGATE TECHNOLOGY LLC, Cupertino, CA (US)

(72) Inventors: Zhaohui Fan, Fremont, CA (US); Yuan Xu, Fremont, CA (US); Justin Jia-Jen Hwu, Fremont, CA (US); Koichi Wago, Sunnyvale, CA (US); David Shiao-Min Kuo, Palo Alto, CA (US)

(21) Appl. No.: 14/315,307

(22) Filed: Jun. 25, 2014

Related U.S. Application Data
(62) Division of application No. 13/173,564, filed on Jun. 30, 2011.

(51) Int. Cl. G11B 5/84; C23C 16/513; C23C 16/455

(52) U.S. Cl. CPC G11B 5/8408; C23C 16/45525; C23C 16/513
USPC 427/127; 118/715

(57) ABSTRACT

The embodiments disclose a method of protecting patterned magnetic materials of a stack, including depositing a thin continuous film of an inert material that is inert to the magnetic materials of a patterned stack upon which the thin continuous film is being deposited and forming a thin interim interface layer from the thin continuous film to protect top and sidewall areas of non-etched higher relief magnetic islands and magnetic film etched surfaces of the patterned stack from air exposure damage and damage from contact with backfilled materials.

### BACKGROUND

Patterned media fabrication processes leave magnetic islands exposed to air and direct contact with backfill materials. The exposure to air and direct contact with backfill materials extends from the top of the magnetic islands to the sidewall surfaces. The exposure may cause chemical reactions that cause physical damage to the magnetic dots and magnetic properties degradation. Backfill materials may cause surface diffusion on the magnetic dot surface that can develop into extraneous metal lattice structures that can change the magnetic properties.

### BRIEF DESCRIPTION OF THE DRAWINGS

FIG. 1 shows a block diagram of an overview of a method of protecting patterned magnetic materials of a stack of one embodiment.

FIG. 2 shows a block diagram of an overview flow chart of a method of protecting patterned magnetic materials of a stack of one embodiment.

FIG. 3A shows for illustrative purposes only an example of freshly patterned magnetic islands of one embodiment.

FIG. 3B shows for illustrative purposes only an example of backfilled materials of one embodiment.

FIG. 3C shows for illustrative purposes only an example of a planarized patterned stack structure including a thin interim interface layer of one embodiment.

FIG. 4A shows for illustrative purposes only an example of a carbon mask pattern on a stack magnetic layer of one embodiment.

FIG. 4B shows for illustrative purposes only an example of a patterned stack magnetic layer of one embodiment.

FIG. 4C shows for illustrative purposes only an example of a deposited thin interim interface layer of one embodiment.

FIG. 4D shows for illustrative purposes only an example of backfilled material deposited on top of a thin interim interface layer of one embodiment.

FIG. 4E shows for illustrative purposes only an example of planarized backfill material and planarized sections of a thin interim interface layer of one embodiment.

### DETAILED DESCRIPTION OF THE INVENTION

In a following description, reference is made to the accompanying drawings, which form a part hereof, and in which is shown by way of illustration a specific example in which the invention may be practiced. It is to be understood that other embodiments may be utilized and structural changes may be made without departing from the scope of the present invention. In a following description, the term magnetic island refers to the top and sidewalls of the higher relief non-etched portions of the patterned magnetic materials of a patterned stack. In a following description, the term magnetic film refers to the lower relief etched surfaces of the patterned magnetic materials of a patterned stack.

### General Overview:

It should be noted that the descriptions that follow, for example, in terms of method of magnetic island protection with sidewall deposition for bit patterned media fabrication is described for illustrative purposes and the underlying system can apply to any number and multiple types patterned stacks and planarization processes. In one embodiment of the present invention, the magnetic dots protection can be configured as a continuous film layer. In other embodiments the continuous film layer includes materials be inert to magnetic island materials and configured to prevent changes in magnetic properties using the present invention.

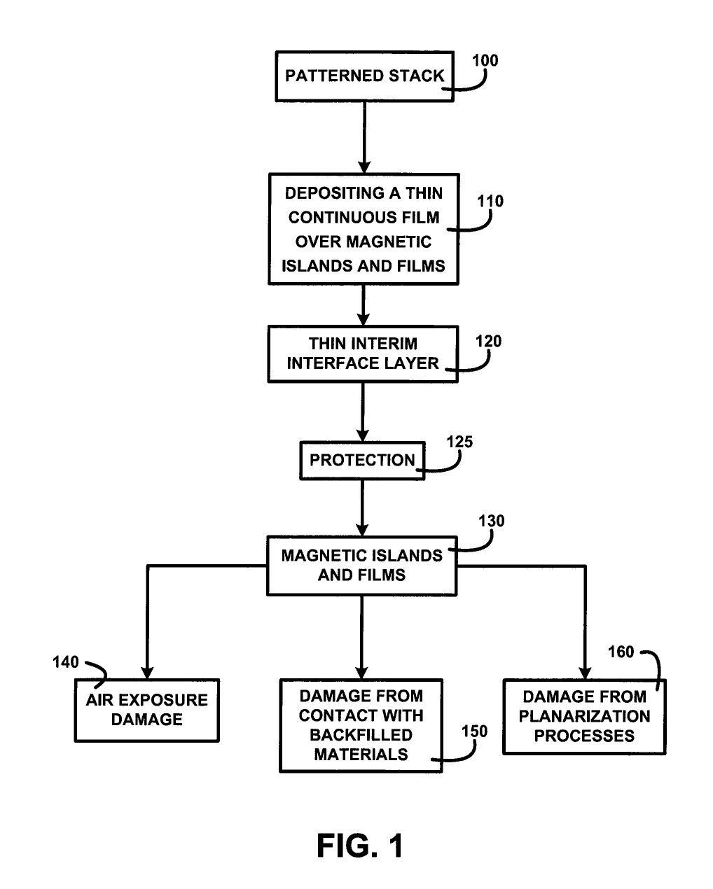

FIG. 1 shows a block diagram of an overview of a method of protecting patterned magnetic materials of a stack of one embodiment. FIG. 1 shows a patterned stack 100 such as a bit-patterned stack. The patterning process for example ion beam etching (IBE) removes a portion of the magnetic materials that form the magnetic layer deposited on a stack substrate. The portions of the magnetic layer materials that are not removed, such as magnetic islands, in a patterning process present a higher relief on the patterned topography. The surfaces of magnetic layer of the patterned stack 100 that have been etched (magnetic films) and the magnetic islands are exposed to air of one embodiment.

The first step in the method of protecting patterned magnetic materials of a stack is depositing a thin continuous film over magnetic islands and films 110. The deposition of the thin continuous film may include materials that are inert to the magnetic materials of the patterned stack 100. The thin continuous film deposition of inert materials is used in forming a thin interim interface layer 120 of one embodiment. The thin interim interface layer 120 is used for creating protection 125 of the magnetic islands and films 130 from damage. Damage to the magnetic islands and films may include air exposure damage 140 such as oxidized Interface surfaces.

The thin interim interface layer 120 insulates the magnetic materials shortly after patterning from being exposed to air and to prevent magnetic properties degradation and physical deterioration. The thin interim interface layer 120 also provides an interface on the side wall surfaces and tops of the magnetic islands and the etched surfaces of the magnetic films of one embodiment.

The interface prevents damage from contact with backfilled materials 150 that may cause a chemical reaction between the backfilled materials and the magnetic materials. The chemical reactions may lead to development of metal lattices which will interfere and alter the magnetic properties of the patterned magnetic structures. Backfilling of the patterned surfaces with materials may include planarization processes to create a smooth surface of the patterned stack topography. The magnetic islands may incur damage from planarization processes 160 such as etch back of the backfilled materials. The method of protecting patterned magnetic materials of a stack provides protection of the patterned magnetic materials over a broad range of material combinations and thereby maintains the intended magnetic properties of the patterned stack of one embodiment.

### DETAILED DESCRIPTION

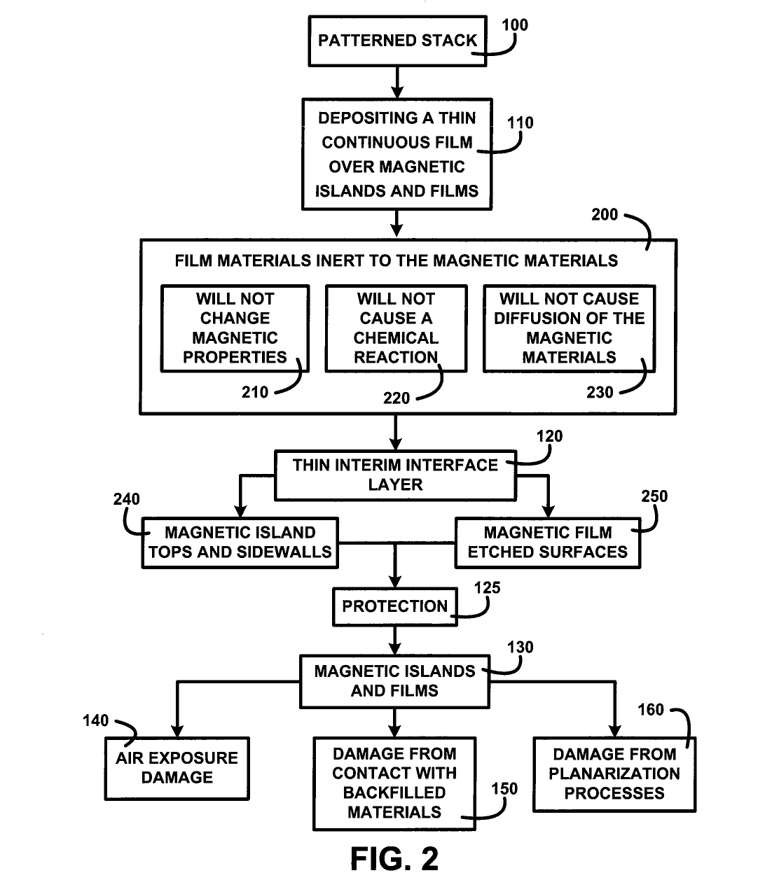

FIG. 2 shows a block diagram of an overview flow chart of a method of protecting patterned magnetic materials of a stack of one embodiment. FIG. 2 shows a patterned stack 100 that may include a bit-patterned stack or discrete track media. Patterning of a stack may include processes such as ion beam etching. The ion beam reacts with the layered structures of the stack, which may include a substrate, magnetic materials layer and a resist layer imprinted using a pattern template. IBE processes may be performed in a vacuum that is free of air of one embodiment.

A step in the method of protecting patterned magnetic materials of a stack may include the depositing a thin continuous film over magnetic islands and films 110. The magnetic islands and films are created by the patterning processes. In one embodiment the deposition of the thin continuous film may be performed in the vacuum environment subsequent to the patterning process. The deposition of the thin continuous film includes using film materials inert to the magnetic materials 200 of the stack. The thin continuous film deposition is used in forming a thin interim interface layer 120 of one embodiment.

The inert film materials in one embodiment is configured to prevent changes in magnetic properties 210 of the magnetic structures of the stack. The inert materials of the thin interim interface layer 120 provide an interface that is configured to prevent a chemical reaction 220 between the magnetic materials and surrounding materials such as those used for backfilling the patterned topography. The thin interim interface layer 120 is configured to prevent diffusion of the magnetic materials 230 of one embodiment.

The depositing of a thin continuous film over magnetic islands and films 110 will cover the magnetic island tops and sidewalls 240 surfaces with the thin interim interface layer 120. The forming of a thin interim interface layer 120 will also deposit inert materials on magnetic film etched surfaces 250. The thin interim interface layer 120 is used for protecting the magnetic islands and films 130 from damage during following fabrication process and beyond. When the patterned stack 100 leaves the vacuum environment the magnetic islands and films 130 may be exposed to air. Air that includes oxygen may react with the magnetic materials and cause air exposure damage 140 of one embodiment.

Following the patterning process the stack topography may be backfilled to create a smooth surface. Forming a thin interim interface layer 120 coats the surfaces of the magnetic islands and magnetic films preventing physical contact with the backfilled materials. The interface coating provided by the inert materials of the thin interim interface layer protects the patterned stack against damage from contact with backfilled materials 150. Contact with the materials used for backfilling may chemically react with the magnetic materials. The contact chemical reaction may cause deterioration of the magnetic materials leading to malfunctions created by changes in the magnetic properties and volume of the patterned magnetic islands. The contact chemical reaction may cause development of metal lattices which could alter the magnetic properties in inconstant ways that would lead to permanent damage in the magnetic islands performance of one embodiment.

The process of backfilling of the stack topography may include planarization processes. The planarization processes are used to reduce height differences on the surface and create a smooth surface on the patterned stack. A finish coating such as a carbon over coat (COC) and lubrication may be deposited upon smooth surface after planarization. Planarization processes may include an etch-back process to chemically remove the remaining mask layer and portions of the backfilled materials. Damage to unprotected magnetic islands may occur including for example chemical reactions with the chemicals used in an etch-back process. Forming a thin interim interface layer 120 that coats the surfaces of the magnetic islands, including the tops and sidewall surfaces, prevents damage from planarization processes 160 such as etch back of one embodiment.

The method of protecting patterned magnetic materials of a stack prevents deterioration and damage to both the magnetic islands and magnetic films of a patterned stack. Damage from exposure to air, contact with backfill materials and planarization processes is prevented by the thin interim interface layer. The protection against damage preserves the physical features and magnetic properties of the magnetic materials of a patterned stack. The thin interim interface layer damage protection thereby increases the quality of patterned stacks such as bit-patterned media of one embodiment.

### Freshly Patterned Magnetic Islands:

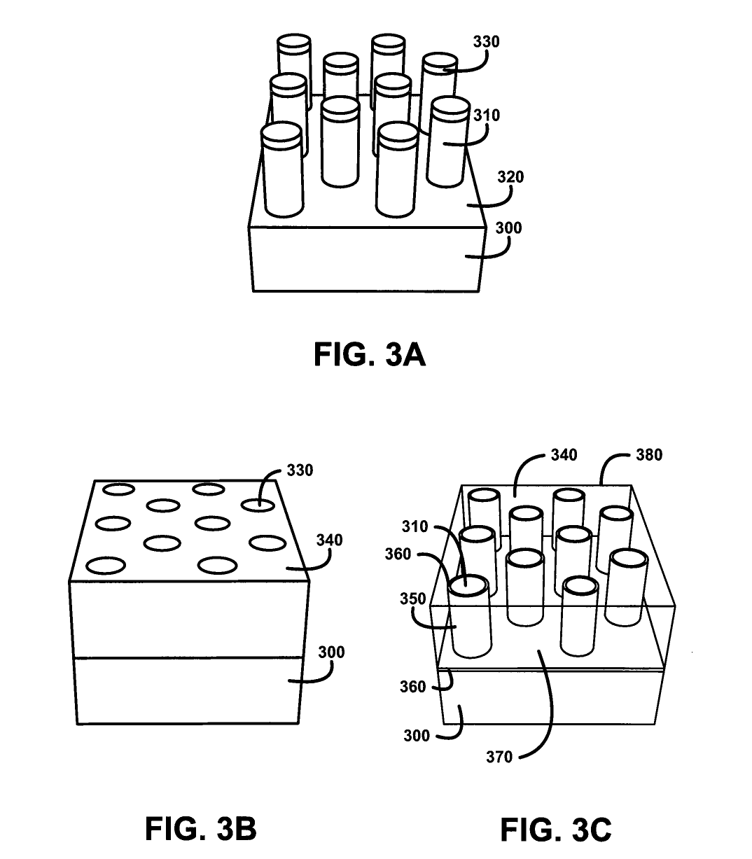

FIG. 3A shows for illustrative purposes only an example of freshly patterned magnetic islands of one embodiment. A patterned stack magnetic layer 300 is shown in FIG. 3A. The full magnetic layer was deposited on a substrate upon which were deposited carbon mask layer and resist layer. A template formed to embed a predetermined template pattern is placed on the resist layer. Portions of the fluid resist layer fill recesses of the template by capillary action. The imprint process hardens each resist filled recess of one embodiment. After removal of the template, the mask formatting processes such as RIE (reactive ion etching) removes unhardened resist and transfers the predetermined resist pattern into the carbon mask layer.

After formation of carbon mask pattern, the magnetic etch processes such as IBE remove the unprotected magnetic materials to a predetermined depth. The magnetic materials remaining under each hardened carbon mask creates a magnetic island 310. The magnetic island 310 appears as a high relief feature on the patterned stack topography with residual etched carbon 330 on top. The areas where the patterning processes have removed magnetic material form etched magnetic film 320 which create a surface below the tops of the magnetic island 310 of one embodiment.

### Backfilling a Patterned Stack:

FIG. 3B shows for illustrative purposes only an example of backfilled materials of one embodiment. FIG. 38 shows the patterned stack magnetic layer 300 that includes a number of magnetic island 310 features and the surfaces of the etched magnetic film 320 of FIG. 3A. FIG. 3B also shows backfilled material 340 where the backfilling deposition is to a thickness to the tops of the etched carbon 330. The backfilled materials 340 may include a planarization process following the deposition of one embodiment.

### Planarized Patterned Stack Structure:

FIG. 3C shows for illustrative purposes only an example of a planarized patterned stack structure including a thin interim interface layer of one embodiment. FIG. 3C shows a transparent view of the backfilled material 340 to allow a view of the patterned features. The magnetic island 310 and etched magnetic film 320 of FIG. 3A features of the patterned stack magnetic layer 300 are visible. A planarization process may include an etch-back process to remove materials to the tops of each magnetic island 310. The etch-back process has removed the etched carbon 330 of FIG. 3A and the thin interim interface layer 360 on top of the etched carbon 330 of FIG. 3A. The etch-back process has also removed a portion of the backfilled material 340 to the etch-back surface of planarization 380 process level.

The thin interim interface layer 360 can be seen up to the top of the etched magnetic film 320 of FIG. 3A. The thin interim interface layer 360 deposited on top of the hardened carbon has been removed to the surface of planarization 380. Sidewall protection 350 provided by the thin interim interface layer 360 remains on the side surfaces of each magnetic island 310 prevent contact with the backfilled material 340. The thin interim interface layer 360 continues to provide magnetic film etched surface protection 370 after the planarization processes are completed on the patterned stack magnetic layer 300 of one embodiment.

### Carbon Mask Pattern:

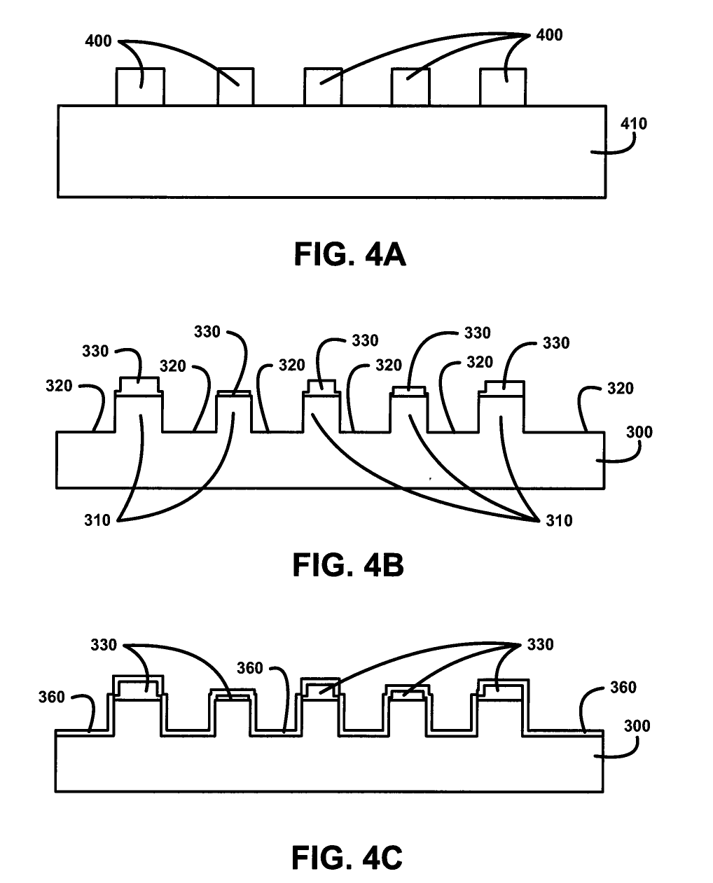

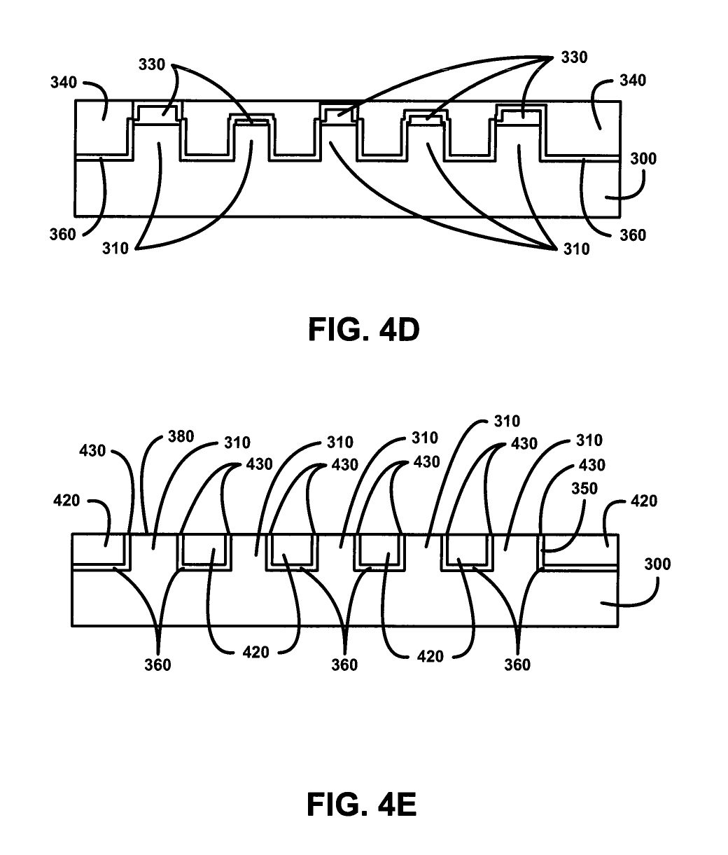

FIG. 4A shows for illustrative purposes only an example of a carbon mask pattern on a stack magnetic layer of one embodiment. FIG. 4A shows a carbon mask pattern 400 developed on a stack magnetic layer 410. The carbon mask formation process may include a resist imprint process using a pattern template with predetermined topography and pattern transferring process into carbon. The continuing magnetic patterning processes continue with for example IBE to transfer the pattern into the stack magnetic layer 410 of one embodiment.

### Patterned Stack Magnetic Layer:

FIG. 4B shows for illustrative purposes only an example of a patterned stack magnetic layer of one embodiment. After the patterning processes have been completed FIG. 4B shows the patterned stack magnetic layer 300. The patterned stack magnetic layer 300 includes magnetic island 310 features created during the patterning processes. On top of each magnetic island 310 are residual etched carbon 330 materials that had been hardened during the patterning processes. The portions of the stack magnetic layer 410 of FIG. 4A that have been removed form the surfaces of the etched magnetic film 320 of one embodiment.

### Thin Interim Interface Layer:

FIG. 4C shows for illustrative purposes only an example of a deposited thin interim interface layer of one embodiment. The method of protecting patterned magnetic materials of a stack includes depositing a thin continuous film over magnetic islands and films 110 of FIG. 1. The deposition of the thin continuous film may includes processes such as sputtering, plasma-enhanced chemical vapor deposition (PECVD), atomic layer deposition and other conformal deposition technique. The deposition of the thin continuous film forms the thin interim interface layer 360 which acts as a protective layer by coating the exposed surfaces of each magnetic island 310 of FIG. 3A and etched magnetic film 320 of FIG. 3A. The thin interim interface layer 360 also coats the exposed surfaces of the residual etched carbon 330 of one embodiment.

The deposition of the thin continuous film may include using a material that is inert to the magnetic materials of a patterned stack. The inert materials may include for example carbon that may be deposited in a thickness of two nm. The inert material is configured to prevent diffusion of the magnetic materials of a patterned stack. The thin interim interface layer will insulate magnetic island from their surroundings including air and backfilled materials. The thin interim interface layer includes application to patterned stack fabrication that includes planarization processes. The thin interim interface layer provides protection against damage in a patterned stack fabrication that may include planarization processes of one embodiment.

### Backfilled Material:

FIG. 4D shows for illustrative purposes only an example of backfilled material deposited on top of a thin interim interface layer of one embodiment. A patterned stack fabrication process may include backfilling the patterned topography of the patterned stack magnetic layer 300. The backfilled material 340 may be deposited on top of the residual etched carbon 330, etched magnetic film 320 of FIG. 3A and the sidewall surfaces of each magnetic island 310 that have been coated with the thin interim interface layer 360.

The backfilled material 340 may be deposited above the heights of each magnetic island 310 and residual etched carbon 330. In one embodiment the patterned stack fabrication process may not include planarization processes. Not including planarization processes would leave the thin interim interface layer 360 intact and provide the protection of the magnetic materials of the patterned stack magnetic layer 300. In another embodiment the patterned stack fabrication process may include planarization processes.

### Planarized Backfill Material:

FIG. 4E shows for illustrative purposes only an example of planarized backfill material and planarized sections of a thin interim interface layer of one embodiment. The backfilled material 340 of FIG. 3B has been reduced in thickness using planarization processes. The removal of backfilled material 340 of FIG. 3B is preformed to a level of a surface of planarization 380. The planarization processes may include an etch-back process that has also removed the residual etched carbon 330 of FIG. 3A and the thin interim interface layer 360 deposited on top of the hardened carbon. The surface of planarization 380 may leave planarized backfill material 420 to the tops of each magnetic island 310 of FIG. 3A. The planarization processes may include mechanical processes to polish the surface leaving planarized thin interim interface layer 430 sections to the tops of each magnetic island 310 of FIG. 3A. The thin interim interface layer 360 has protected the magnetic materials from damage during the planarization processes.

The surface of planarization 380 may leave planarized backfill material 420 below the tops of each magnetic island 310 of FIG. 3A. This would expose the thin interim interface layer 360 to the chemical materials used for example in an etch-back process. The thin interim interface layer 360 provides magnetic island 310 of FIG. 3A sidewall protection 350 from damage that may be caused by the etch-back process chemical materials. The patterned stack magnetic layer 300 has been protected from physical damage and magnetic volume loss during planarization processes using the thin interim interface layer 360 of one embodiment.

The foregoing has described the principles, embodiments and modes of operation. However, the invention should not be construed as being limited to the particular embodiments discussed. The above described embodiments should be regarded as illustrative rather than restrictive, and it should be appreciated that variations may be made in those embodiments by workers skilled in the art without departing from the scope as defined by the following claims.

What is claimed is:

1. A method of protecting patterned magnetic materials of a stack, comprising:
depositing a thin continuous film of an inert material that is inert to the magnetic materials of a patterned stack upon which the thin continuous film is being deposited; and
forming a thin interim interface layer from the thin continuous film to protect top and sidewall areas of non-etched higher relief magnetic islands and magnetic film etched surfaces of the patterned stack from air exposure damage and damage from contact with backfilled materials.

2. The method of claim 1, wherein the inert material is configured to prevent changes to magnetic properties of the magnetic islands and magnetic films of the patterned stack.

3. The method of claim 1, wherein the inert material is configured to prevent a chemical reaction with the magnetic materials of a patterned stack.

4. The method of claim 1, wherein the inert material is configured to prevent diffusion of the magnetic materials of a patterned stack.

5. The method of claim 1, wherein depositing the thin continuous film includes at least one of sputtering, plasma-enhanced chemical vapor deposition, atomic layer deposition or conformal deposition.

6. The method of claim 1, wherein the thin interim interface layer includes a planarization processes.

7. The method of claim 1, wherein the thin interim interface layer is configured to insulate magnetic island from surrounding elements including air and backfilled materials.

8. The method of claim 1, wherein the thin interim interface layer is configured to create magnetic island sidewall protection from damage during planarization and etch back processes.

9. The method of claim 1, wherein the thin continuous film is deposited over freshly patterned magnetic islands subsequently after ion beam etching patterning in a vacuum.

10. An apparatus, comprising:
means for depositing a thin continuous film of an inert material that is inert to the magnetic materials of a patterned stack upon which the thin continuous film is being deposited; and
means for forming a thin interim interface layer from the thin continuous film to protect top and sidewall areas of non-etched higher relief magnetic islands and magnetic film etched surfaces of the patterned stack from air exposure damage and damage from contact with backfilled materials.

11. The apparatus of 10, further comprising means for creating a thin interim interface layer structure in a patterned stack to protect magnetic islands during planarization processes.

12. The apparatus of 10, further comprising means for depositing the inert material to prevent changes to magnetic properties of the patterned stack.

13. The apparatus of 10, wherein the means for depositing the thin continuous film includes at least one of means for sputtering, means for plasma-enhanced chemical vapor deposition, means for atomic layer deposition or means for conformal deposition.

14. The apparatus of 10, further comprising means for creating a thin interim interface layer structure in a patterned stack to protect magnetic islands from diffusion damage by direct contact with backfilled materials.

15. The apparatus of 10, further comprising means for depositing the thin continuous film over freshly patterned magnetic islands of a patterned stack subsequently after ion beam etching patterning in a vacuum.
